(19) United States
(12) Patent Application Publication
(10) Pub. No.: US 2007/0059549 A1
(43) Pub. Date: Mar. 15, 2007

(54) Metallic pattern for manufacturing prism sheet and method of manufacturing the same

(76) Inventors: Seong Yong Hwang, Yongin-Si (KR); Joong Hyun Kim, Suwon-Si (KR); Sang Yu Lee, Yongin-Si (KR)

Correspondence Address: CANTOR COLBURN, LLP, 55 GRIFFIN ROAD SOUTH, BLOOMFIELD, CT, 06002, US

(21) Appl. No.: 11/362,660

(22) Filed: Feb. 27, 2006

(30) Foreign Application Priority Data
Sep. 12, 2005 (KR) 10-2005-0084796

(51) Int. Cl. H05K 3/38; B32B 15/01; B05D 1/12; B05D 3/02

(52) U.S. Cl. 428/612; 428/647; 428/648; 428/687; 427/372.2; 427/331; 427/180

(57) ABSTRACT

Disclosed are a metallic pattern for manufacturing a prism sheet having a micro-pattern capable of diffusing light and a method of manufacturing such a metallic pattern. The method includes preparing a metallic plate, coating a solder containing tin (Sn) on the metallic plate, heat-treating the metallic plate and the solder for a first time at a first temperature to form a micro-pattern between the metallic plate and the solder, and selectively removing the solder from the metallic plate where the micro-pattern is formed.

This application claims priority to Korean Patent Application No. 10-2005-0084796, filed on Sep. 12, 2005 and all the benefits accruing therefrom under 35 U.S.C. §119, and the contents of which in its entirety are herein incorporated by reference.

### BACKGROUND OF THE INVENTION

1. Field of the Invention

The present invention relates to a metallic pattern for manufacturing a prism sheet and a method of manufacturing the metallic pattern, and more particularly, to a metallic pattern for manufacturing a prism sheet having a micro-pattern capable of diffusing light and a method of manufacturing such a metallic pattern.

2. Description of the Related Art

In general, a liquid crystal display (“LCD”) device has various advantageous features such as a lightweight structure, slim shape, low power consumption, full-color implementation, high resolution, and the like. As such, its application fields have been increasingly widened. Presently, LCD devices are employed in computers, notebooks, PDAs, telephones, TV sets, audio/video devices and the like. In such an LCD device, depending upon image signals applied to a plurality of control switches arranged in a matrix pattern, the light transmissivity is controlled to display a desired image on an LCD panel. The LCD device is not a self light-emitting device and thus needs a light source such as a backlight.

FIG. 1 is an exploded perspective view of a common edge-type backlight unit for an LCD device. Referring to FIG. 1, the backlight unit includes a lamp 1, a reflection plate 2, a waveguide plate 3, a diffusion plate 4, a first prism sheet 5, a second prism sheet 6, and a protection sheet 7. An LCD panel 8 is positioned relative to the backlight unit as shown.

Visible light emitted from the lamp 1 is directed to an edge of the waveguide plate 3 having a slant bottom face. Formed in the bottom face of the waveguide plate 3 are various patterns such as a fine dot pattern for changing the traveling path of the visible light from the lamp 1 toward the LCD panel 8, so that light loss can be reduced and simultaneously, the patterns on the waveguide plate 3, together with the reflection plate-2, guides the light upwardly towards the LCD panel 8. At this time, the light passing through the top face of the waveguide plate 3 includes light emitted perpendicularly to the top face and also lights emitted in various directions.

The diffusion plate 4 disperses lights incident from the waveguide plate 3, thereby preventing the lights from being locally concentrated and reducing inclination angle of the advancing light with respect to the first prism sheet 5.

The first prism sheet 5 and the second prism sheet 6 have triangular prisms arranged in a regular pattern on their respective top surfaces, which intersect with each other. By means of the first prism sheet 5 and the second prism sheet 6, the light diffused from the diffusion plate 4 is condensed in a direction perpendicular to the plane of the LCD panel 8. The protection sheet 7 is disposed above the second prism sheet 6, between the second prism sheet 6 and the LCD panel 8, and protects the prism sheets 5, 6.

FIG. 2 shows a structure of the conventional prism sheet. Referring to FIG. 2, the prism sheet is composed of an upper prism sheet and a lower prism sheet. The upper prism sheet has a plurality of triangular prisms arranged on a top face thereof in a Y-axis direction, and the lower prism sheet has a plurality of triangular prisms arranged on a top face thereof in an X-axis direction. The prism sheet can change lights incident in X-axis and Y-axis directions into a frontward direction (Z-axis direction), but the prism sheet must be composed of two prism sheets including upper and lower prism sheets as shown. In addition light loss occurs while light passes through the upper prism sheet and the lower prism sheet.

FIGS. 3A and 3B show schematic sectional views of a conventional prism sheet having a diffusion function. In the prism sheet shown in FIG. 3A, a fine light-scattering pattern having a linear arrangement is repeated and regularly formed in the top face of the depressed and prominent prism, thereby performing or compensating for the function of a diffusion plate. Alternatively, as shown in FIG. 3B, a light-diffusion film having beads is attached to the top face of the prisms in order to provide a diffusion function, thereby realizing a lightweight, thinly shaped and miniaturized backlight unit.

The above fine light-scattering pattern as shown in FIG. 3A may be directly formed on the top face of the prisms using a sandblast or the like, or through a screen-printing or an injection transferring film. In the sandblast method, however, the sand particle has a larger size relative to the depression and prominence of the prism, which may become destroyed. In addition, according to the above processes, after the prism sheet is fabricated, an additional process is required to form a fine light-scattering pattern, thereby resulting in complexity in the manufacturing process and an increase in the manufacturing cost. Furthermore, according to the above methods, the fine light-scattering pattern may not be clearly formed so that a diffusion function cannot be performed.

### BRIEF SUMMARY OF THE INVENTION

The present invention solves the aforementioned problems in the art by providing a metalic pattern for manufacturing a prism sheet, which has a micro-pattern formed thereon to thereby provide a diffusion function and a condensing function, and a method of manufacturing such a metallic pattern.

According to exemplary embodiments of the present invention, a method of manufacturing a metallic pattern for manufacturing a prism sheet includes preparing a metallic plate, coating a solder containing tin (Sn) on the metallic plate, heat-treating the metallic plate and the solder for a first time at a first temperature to form a micro-pattern between the metallic plate and the solder, and selectively removing the solder from the metallic plate where the micro-pattern is formed.

Coating a solder on the metallic plate may further include applying the solder in a powder form on the metallic plate and then melting the solder.

Coating a solder on the metallic plate may instead include coating the solder in a melted form on the metallic plate.

The metallic plate may be formed of nickel or copper.

The metallic plate may instead be formed by plating nickel or copper.

The solder may be selected from the group consisting of a Pb—Sn alloy, a Sn—Bi alloy, a Sn—In—Ag alloy, a Sn—Ag—Cu alloy and a Sn—Zn alloy.

Selectively removing the solder on the metallic plate may include etching using HCl or HNO₃.

The micro-pattern formed between the metallic plate and the solder is an interface compound formed through reaction between the metallic plate and the solder.

Preparing the metallic plate may further include forming a plurality of depressions and prominences having a shape on the metallic plate.

The plurality of depressions and prominences may be formed to have a polygonal cone shape.

The plurality of depressions and prominences may be arranged in one axial direction and formed to have a polygonal cross-section.

Heat-treating the metallic plate and the solder for a first time at a first temperature to form a micro-pattern between the metallic plate and the solder includes forming a convexly shaped micro-pattern between the metallic plate and the solder.

After the metallic-plate and the solder are heat-treated for the first time at the first temperature, the metallic plate and the solder may be heat-treated for a second time at a second temperature to grow the micro-pattern formed between the metallic plate and the solder. According to other exemplary embodiments of the present invention, there is provided a metallic pattern for manufacturing a prism sheet, where the metallic pattern is manufactured through the above-described method.

The exemplary embodiments of the method of the present invention may further include coating a release agent on the micro-pattern, forming a metallic layer on the release agent, and separating the metallic layer from the metallic plate where the micro-pattern is formed.

The metallic layer is formed by plating a metal containing nickel.

Forming the metallic layer on the release agent includes forming a concavely shaped micro-pattern on the metallic layer.

According to other exemplary embodiments of the present invention, a metallic pattern for use in manufacturing a prism sheet includes a metallic plate having a plurality of depressions and prominences arranged in a same axial direction, and a micro-pattern formed on a surface of the plurality of depressions and prominences, wherein the micro-pattern is an interface compound formed through a reaction between the metallic plate and a solder applied to the metallic plate to create the interface compound through heat treatment.

The plurality of depressions and prominences may have a substantially triangular cross-section.

The metallic plate may include nickel and the micro-pattern may include a compound of nickel and tin.

The micro-pattern may be convexly shaped on the metallic plate.

According to other exemplary embodiments of the present invention, a metallic pattern for use in manufacturing a prism sheet includes a plated layer having a plurality of depressions and prominences arranged in a same axial direction, the plurality of depressions and prominences having a substantially triangular cross-section, and a micro-pattern formed on a surface of the plurality of depressions and prominences, wherein the micro-pattern is concavely shaped on the plated layer.

The plated layer may be formed of nickel.

The micro-pattern on the plated layer may be formed by forming the plated layer over a micro-pattern on a metallic plate, the micro-pattern on the metallic plate being an interface compound created through a reaction between the metallic plate and a solder applied to the metallic plate to create the interface compound through heat treatment.

### BRIEF DESCRIPTION OF THE DRAWINGS

The above and other features and advantages of the present invention will become apparent from the following description of a preferred embodiment given in conjunction with the accompanying drawings, in which:

FIG. 1 is an exploded perspective view of a common backlight unit for an LCD device;

FIG. 2 shows a structure of a conventional prism sheet;

FIGS. 3A and 3B show schematic sectional views of a conventional prism sheet having a diffusion function;

FIGS. 4A to 4C show sectional views illustrating a first exemplary embodiment of manufacturing procedures of a metallic pattern for manufacturing a prism sheet according to the present invention;

FIG. 5 is a flow chart of a second exemplary embodiment of a process for manufacturing a metallic pattern for production of a prism sheet according to the present invention;

FIGS. 6A and 6B show photographs of an interface compound (micro-pattern) formed on the metallic plate through different heat-treating conditions; and

FIGS. 7A to 7C are sectional views illustrating a third exemplary embodiment of a process for manufacturing a metallic pattern for production of a prism sheet according to the present invention;

FIGS. 8A and 8B show schematic views of a metallic pattern and a prism sheet, respectively, where the prism sheet is fabricated using either the first and second exemplary embodiments of a metallic pattern formed according to the present invention; and

FIGS. 8C and 8D show schematic views of a metallic pattern and prism sheet, respectively, where the prism sheet is fabricated using the third exemplary embodiment of a metallic-pattern formed according to the present invention.

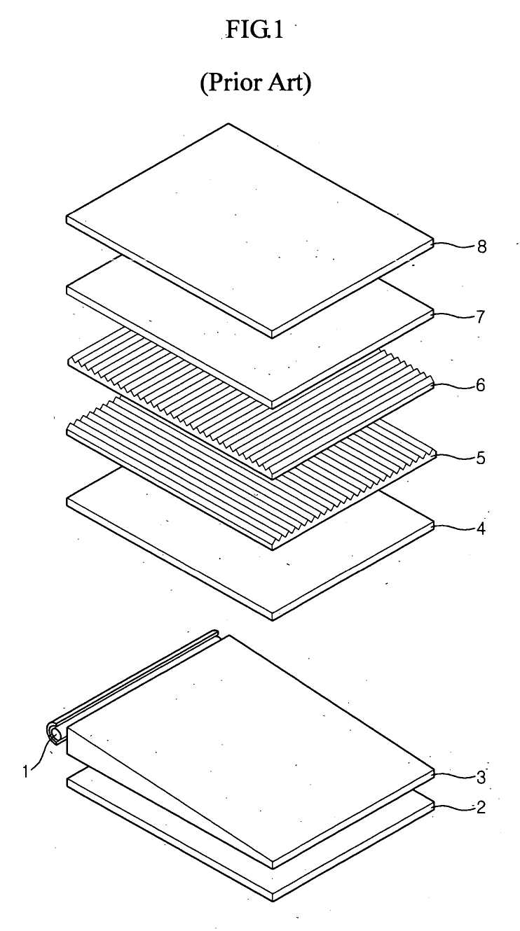

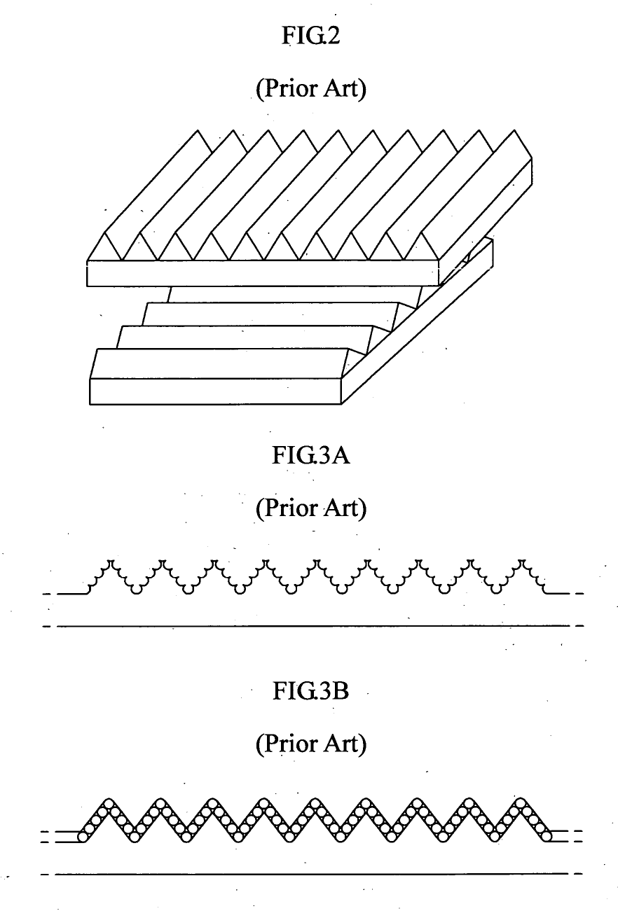

### DETAILED DESCRIPTION OF THE INVENTION

Hereinafter, a preferred embodiment of the invention will be described in detail with reference to the accompanying drawings. In the drawings, the thickness and dimensions of certain regions are exaggerated for clarity. Like numerals refer to like elements throughout.

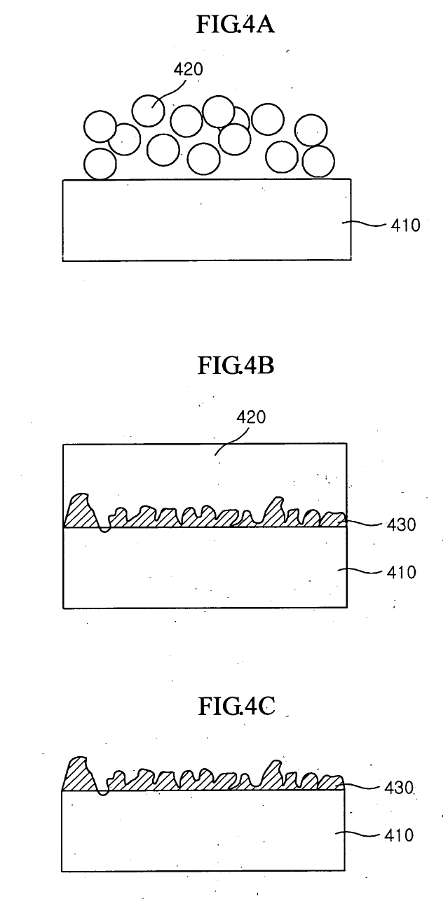

FIGS. 4A to 4C show sectional views illustrating a first exemplary embodiment of manufacturing procedures of a metallic pattern for manufacturing a prism sheet according to the present invention.

Referring to FIG. 4A, first, a metallic plate 410 is prepared, which is formed of a material generally used for making an injection mold or a stamper. The metallic plate 410 may be formed of nickel (“Ni”) or a nickel-plated plate. Although the metallic plate 410 is described as being made of Ni, the metallic plate 410 is not limited thereto. For example, the metallic plate 410 may alternatively be formed of copper (“Cu”) or other metallic materials.

As shown in FIG. 4A, the metallic plate 410 has a flat surface, but, alternatively, a plurality of depressions and prominences having a desired shape may be formed on the surface. The depressions and prominences may be formed to have a polygonal cone shape and arranged in one axial direction. The cross-section thereof may have a triangular shape. Other shapes and cross-sections of the depressions and prominences on the surface of the metallic plate 410 would also be within the scope of these embodiments.

Then, a solder 420 formed of lead-tin (“Pb—Sn”) alloy is coated on the metallic plate 410 in the form of powder. While the solder 420 is described as made of Pb—Sn alloy, the solder 420 is not limited thereto. For example, the solder 420 may alternatively be formed of an alloy containing tin (“Sn”), such as tin-bismuth (“Sn—Bi”) alloys, tin-indium-silver (“Sn—In—Ag) alloys, tin-silver-copper (“Sn—Ag—Cu”) alloys, tin-zinc (“Sn—Zn”) alloys, or the like.

Referring to FIG. 4B, after the powder solder 420 made of Pb—Sn alloy, or other material as described above, is coated on the metallic plate 410, a heat-treatment is performed to melt the solder 420. Thus, FIG. 4B shows the solder 420 in a melted condition.

As described above, when the heat-treatment is performed, an interface compound, i.e., a micro-pattern 430 (hereinafter, the interface compound is referred to as a “micro-pattern”) is formed on the interface between the surface of the metallic plate 410 and the solder 420. The micro-pattern 430 has the form shown in FIG. 4B and the shape and size of the micro-pattern 430 can be controlled, depending upon the conditions of the heat-treatment. In one exemplary embodiment, where Ni is used in the metallic plate 410 and Sn is used in the solder 420, the Ni of the metallic plate 410 and Sn of the solder 420 are reacted to form the micro-pattern 430, and the chemical formula of the micro-pattern 430 is Ni₃Sn₄.

Alternatively, when the metallic plate 410 is made of Cu and the solder 420 includes Sn, the micro-pattern 430 formed in the interface between the metallic plate 410 and the solder 420 constitutes Cu₆Sn₅.

Also, in addition to the heat-treatment to melt the solder 420, an additional heat-treatment may be performed for a desired time at a desired temperature. By means of this additional heat-treatment, the size of the micro-pattern 430 can be grown. Thus, the size of the micro-pattern 430 can be controlled based on the duration and temperature of the additional heat-treatment.

Referring to FIG. 4C, after the micro-pattern 430 is formed between the metallic plate 410 and the solder 420 through the heat treatment, the solder 420 above the metallic plate 410 is selectively removed.

While maintaining the micro-pattern 430 formed between the metallic plate 410 and the solder 420, only the solder 420 is removed. For this purpose, an etching solution, such as hydrogen chloride, where a solution of the gas in water forms hydrochloric acid (“HCl”), or nitric acid (“HNO₃”), is used to etch just the solder 420. As a result, as shown in FIG. 4C, the metallic plate 410 and the micro-pattern 430 formed thereabove remain. While particular etching solutions are described, it should be understood that those etching solutions are exemplary only, and that alternative etching solutions for maintaining the micro-pattern 430 on the metallic plate 410 while the solder 420 is removed would also be within the scope of these embodiments. The metallic plate 410 and micro-pattern 430 thus form a metallic pattern for the manufacture of a prism sheet, as will be further described below.

If a prism sheet is fabricated using the metallic pattern shown in FIG. 4C manufactured through the above-described process, the prism sheet will have depressions and prominences having a desired shape, and a micro-pattern will be formed on the top, surface of the depressions and prominences of the prism sheet. Thus, a prism sheet having a diffusion function and also a condensing function can be provided.

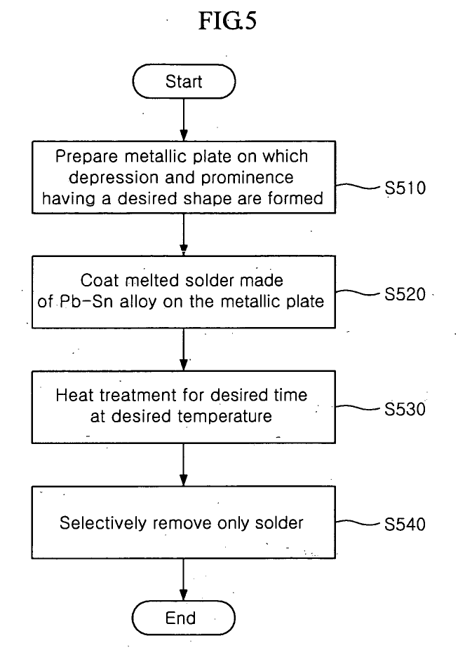

FIG. 5 is a flow chart of a second exemplary embodiment of manufacturing process of a metallic pattern for production of a prism sheet according to the present invention. The second exemplary embodiment of the present invention demonstrated in FIG. 5 is similar to the first exemplary embodiment illustrated in FIGS. 4A to 4C, except that a melted solder is coated on the metallic plate instead of a powdered solder. Hereinafter, the second exemplary embodiment will be described, focusing on the above-mentioned difference from the first exemplary embodiment.

Referring to FIG. 5, first, as shown in step S510, a metallic plate is prepared, which has a plurality of depressions and prominences having a desired shape. At this time, the metallic plate may be formed of Ni or may be an Ni-plated plate. As previously described with respect to the first exemplary embodiment, the material for the metallic plate is not limited to nickel. For example, copper or other metals may be used for the metallic plate. Also, the depressions and prominences on the metallic plate may include, but are not limited to, depressions and prominences having a polygonal cone shape arranged in one axial direction and having a cross-section of a triangular shape. Other shapes and cross-sections of the depressions and prominences of the metallic plate would also be within the scope of these embodiments.

Thereafter, as shown in step S520, a melted solder made of a Pb—Sn alloy is coated on the metallic plate. Coating the melted solder onto the metallic plate may be done, for example, by dipping the metallic plate into a melted solder, or through various other ways. In addition, as previously described, the melted solder need not be made of Pb—Sn alloy, but may instead be formed of an alloy containing Sn, such as Sn—Bi alloys, Sn—In—Ag alloys, Sn—Ag—Cu alloys, Sn—Zn alloys, or the like.

Then, as shown in step S530, a heat treatment is performed for a desired period of time at a desired temperature on the metallic plate and solder. Through the heat-treatment, an interface compound, i.e., a micro-pattern, is formed in the interface between the metallic plate and the solder. The size of the micro-pattern 430 can be controlled based on the duration and temperature of the heat-treatment process.

Finally, as shown in step S540, only the solder is selectively removed from the metallic plate. That is, while maintaining the micro-pattern formed between the metallic plate and the solder, only the solder is removed. For removing the solder while maintaining the micro-pattern on the metallic plate, an etching solution, such as HCl or HNO₃, is used to etch just the solder. While particular etching solutions are described, it should be understood that those etching solutions are exemplary only, and that alternative etching solutions for maintaining the micro-pattern on the metallic plate while the solder is removed would also be within the scope of these embodiments. The metallic plate and micro-pattern thus form a metallic pattern for the manufacture of a prism sheet, as will be further described below.

In the first and second exemplary embodiments as described above with respect to FIGS. 4A to 5, because the metallic pattern has a convex micro-pattern, a prism sheet produced using the metallic pattern of either of the first and second exemplary embodiments will have a concave micro-pattern formed thereon.

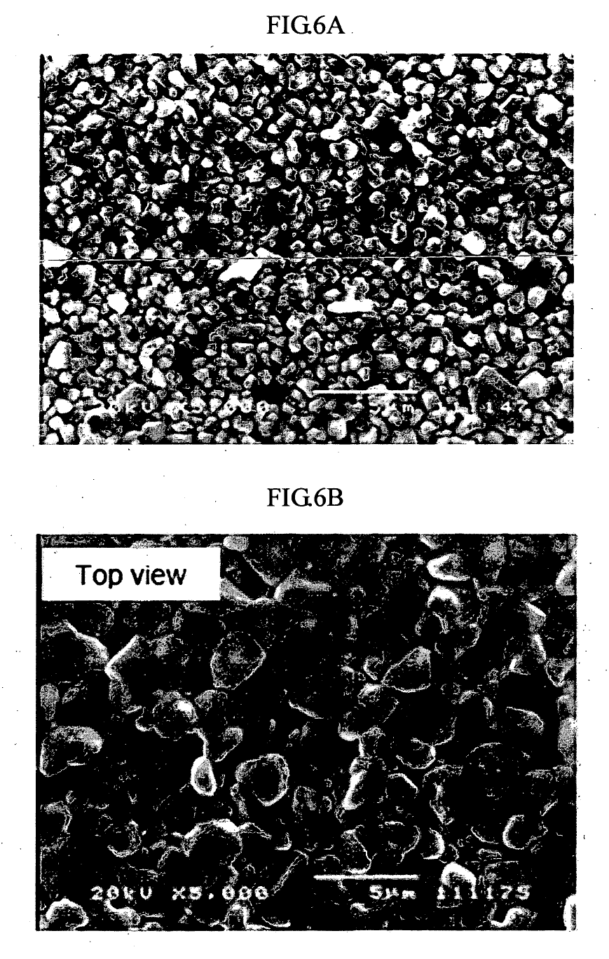

FIGS. 6A and 6B show photographs of an interface compound (micro-pattern) formed on the metallic plate through different heat-treating conditions.

FIG. 6A shows a micro-pattern formed in the interface between a nickel-plated metallic plate and a solder made of Pb—Sn alloy when the heat-treatment is performed to the extent for the solder to be melted, preferably at 220˜230° C., after coating the solder on the metallic plate.

FIG. 6B shows a micro-pattern formed in the interface between the nickel-plated metallic plate and the solder when an additional heat-treatment is performed for about 100 hours at 150° C. after the heat-treatment of FIG. 6A is concluded.

Comparing FIG. 6A and FIG. 6B to each other, it can be seen that the additional heat-treatment allows the micro-pattern to be grown into a larger size, and therefore it should be understood that variations of the size of the micro-pattern may be accommodated by adjusting a duration and temperature of the additional heat-treatment.

Since a degree of light-diffusion and condensation varies with the size of the micro-pattern formed on a prism sheet, the size of the micro-pattern needs to be controlled. Thus, when forming the micro-pattern on the metallic pattern, the conditions of heat-treatment can be varied to obtain a desired size of the micro-pattern on the metallic pattern, thus affecting a size of a micro-pattern on a prism sheet manufactured using the metallic pattern.

Additionally, the size of the micro-pattern on the metallic pattern can be varied with the composition of the solder, along with the heat-treating condition. That is, different compositions of the solder will differently affect a resultant size of the micro-pattern obtained in the interface between the metallic plate and the solder.

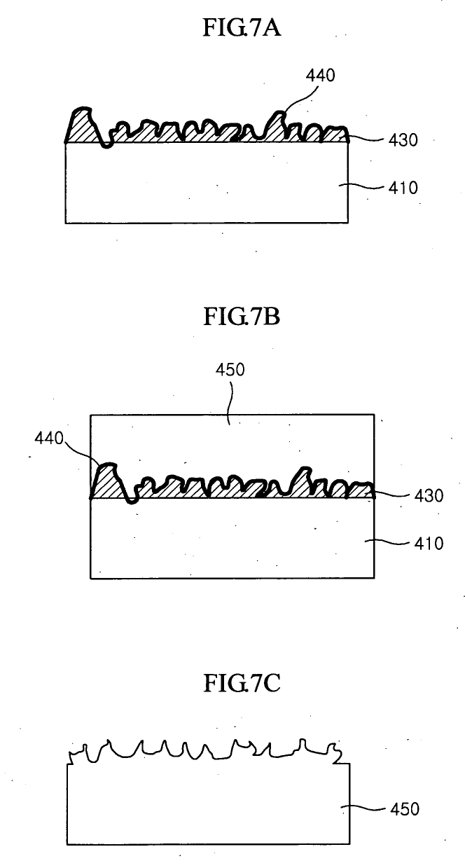

FIGS. 7A to 7C are sectional views illustrating a third exemplary embodiment of a process for manufacturing a metallic pattern for production of a prism sheet according to the present invention.

As shown in FIGS. 7A to 7C, the third exemplary embodiment of the present invention is directed to a process for forming a concave micro-pattern for a metallic pattern, where additional processes for changing the shape of the micro-pattern are performed, in addition to the methods of manufacturing the metallic pattern according to the first and second exemplary embodiments of the present invention.

Therefore, hereafter, the process for changing the shape of the micro-pattern will be described and details on the same procedures as in the first and second exemplary embodiments will be omitted.

First, a metallic plate 410 is prepared, which has a convex micro-pattern 430 formed according to either the first or second exemplary embodiments, as previously described with respect to FIGS. 4A to 5.

Referring to FIG. 7A, a release agent 440 is coated on the micro-pattern 430. The release agent 440 is coated on the micro-pattern 430 for easily separating the plated layer (as will be further described below) from the metallic plate 410 having the micro-pattern 430 formed thereon

Referring to FIG. 7B, thereafter, a plated layer 450 is formed. Here, the plated layer may be formed of nickel, but is not limited thereto. Other metallic materials may alternatively be employed for the plated layer 450.

Then, as shown in FIG. 7C, if the metallic plate 410 with the micro-pattern 430 is separated from the plated layer 450, which is made possible by the release agent 440, a plated layer 450 having a concave micro-pattern can be obtained. The resultant plated layer 450 having the concave micro-pattern thus serves as a metallic pattern for the production of a prism sheet. When a prism sheet is manufactured using a metallic pattern formed according to this embodiment, a convex micro-pattern can be formed on the prism sheet.

According to the above-described exemplary embodiments of the invention, the micro-pattern can be very densely formed on the metallic pattern for manufacturing a prism sheet as shown, for example, in FIGS. 6A and 6B.

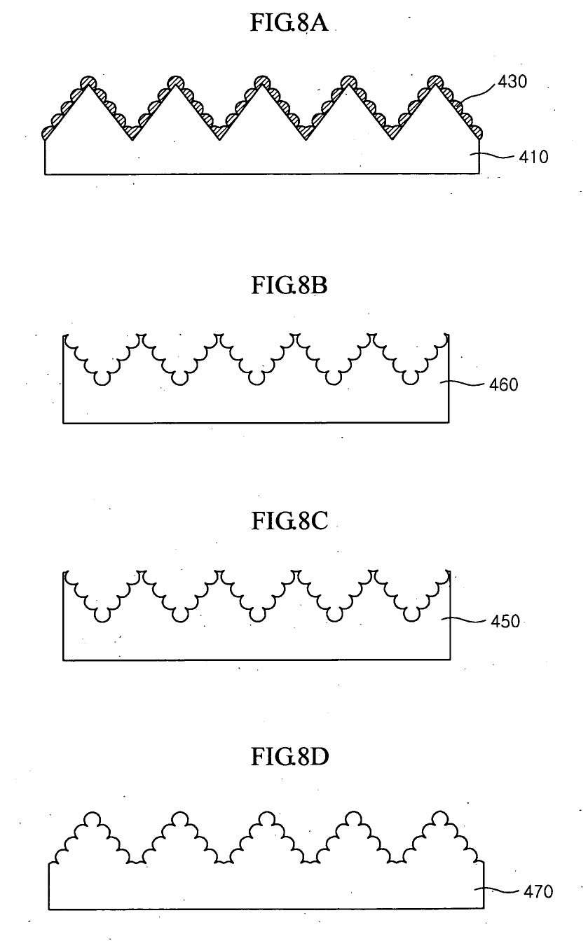

FIGS. 8A and 8B schematically show a metallic pattern and a prism sheet, respectively, where the prism sheet is fabricated using the metallic pattern formed according to either the first and second exemplary embodiments of the present invention.

FIG. 8A illustrates the metallic pattern for manufacturing a prism sheet according to the first and second exemplary embodiments of the present invention. The metallic pattern is formed of a metallic plate 410, on which a plurality of depressions and prominences arranged in one axial direction and having a triangular cross-section are formed. On the faces of the depressions and prominences are formed a plurality of convex micro-patterns 430. In this embodiment, the depressions and prominences are illustrated as having a plurality of triangular projections, but may alternatively be formed in various other shapes, as previously described.

FIG. 8B illustrates a prism sheet 460 fabricated using the metallic pattern of FIG. 8A. The prism sheet 460 is fabricated by stamping, injection molding, extruding or casting an optical film, for example, a transparent optical polyester film, using the metallic pattern of FIG. 8A.

As shown in FIG. 8B, on the prism sheet 460 manufactured as described above is formed a concave micro-pattern, on the top face of the depressions and prominences having a triangular cross-section.

FIGS. 8C and 8D schematically show a metallic pattern and a prism sheet, respectively, where the prism sheet is fabricated using the metallic pattern formed according to the third exemplary embodiment of the present invention.

FIG. 8C illustrates the metallic pattern for manufacturing a prism sheet according to the third exemplary embodiment of the present invention. The metallic pattern is formed of a plated layer 450, as previously described with respect to FIG. 7C, on which a plurality of depressions and prominences arranged in one axial direction and having a triangular cross-section are formed. On the faces of the depressions and prominences are formed a concave micro-pattern. In this exemplary embodiment, the depressions and prominences are illustrated as having a plurality of triangular projections, but may alternatively be formed in various other shapes, as described above.

FIG. 8D illustrates a prism sheet 470 fabricated using the metallic pattern of FIG. 8C. As shown in FIG. 8D, on the prism sheet 470 is formed a convex micro-pattern on the top faces of the depressions and prominences having a triangular cross-section.

As described above, according to the invention, a metallic pattern for manufacturing a prism sheet having a-diffusion function and a condensing function can be easily fabricated by forming a micro-pattern for light diffusion.

In addition, the micro-pattern having various sized can be provided, depending upon conditions of a heat-treatment and solder composition.

Furthermore, using the metallic pattern of the invention, a prism sheet having a micro-pattern formed thereon can be manufactured, which can improve light-efficiency and provide a slim backlight unit.

Although the metallic pattern for manufacturing a prism sheet and the method of manufacturing the same according to the present invention have been illustrated and described in connection with the preferred exemplary embodiments, is the exemplary embodiments have been presented only for illustrative purposes. It will be readily understood by those skilled in the art that various modifications and changes can be made thereto without departing from the spirit and scope of the present invention defined by the appended claims. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. A method of manufacturing a metallic pattern for manufacturing a prism sheet, the method comprising:
preparing a metallic plate;
coating a solder containing tin Sn on the metallic plate;
heat-treating the metallic plate and the solder for a first time at a first temperature to form a micro-pattern between the metallic plate and the solder; and
selectively removing the solder from the metallic plate where the micro-pattern is formed.

2. The method as claimed in claim 1, wherein coating a solder on the metallic plate further includes applying the solder in a powder form on the metallic plate and then melting the solder.

3. The method as claimed in claim 1, wherein coating a solder on the metallic plate includes coating the solder in a melted form on the metallic plate.

4. The method as claimed in claim 1, wherein preparing a metallic plate includes providing a metallic plate comprising nickel or copper.

5. The method as claim in claim 4, wherein providing the metallic plate comprising nickel or copper includes forming the metallic plate by plating nickel or copper.

6. The method as claimed in claim 1, wherein the solder comprises solder selected from the group consisting of a Pb—Sn alloy, a Sn—Bi alloy, a Sn—In—Ag alloy, a Sn—Ag—Cu alloy and a Sn—Zn alloy.

7. The method as claimed in claim 1, wherein selectively removing the solder on the metallic plate includes etching the solder using HCl or HNO₃.

8. The method as claimed in claim 1, wherein the micro-pattern formed between the metallic plate and the solder is an interface compound formed through reaction between the metallic plate and the solder.

9. The method as claimed in claim 1, wherein preparing a metallic plate includes forming a plurality of depressions and prominences having a shape on the metallic plate.

10. The method as claimed in claim 9, wherein forming a plurality of depressions and prominences includes forming the plurality of depressions and prominences to have a polygonal cone shape.

11. The method as claimed in claim 9, wherein forming a plurality of depressions and prominences includes arranging the plurality of depressions and prominences in one axial direction and forming the plurality of depressions and prominences to have a polygonal cross-section.

12. The method as claimed in claim 1, further comprising heat-treating the metallic plate and the solder for a second time at a second temperature to grow the micro-pattern formed between the metallic plate and the solder after the metallic plate and the solder are heat-treated for the first time at the first temperature.

13. The method as claimed in claim 1, wherein heat-treating the metallic plate and the solder for a first time at a first temperature to form a micro-pattern between the metallic plate and the solder comprises forming a-convexly shaped micro-pattern between the metallic plate and the solder.

14. The method as claimed in claim 1, further comprising:
coating a release agent on the micro-pattern;
forming a metallic layer on the release agent; and
separating the metallic layer from the metallic plate where the micro-pattern is formed.

15. The method as claimed in claim 14, wherein forming a metallic layer on the release agent includes forming the metallic layer by plating a metal containing nickel.

16. The method as claimed in claim 14, wherein heat-treating the metallic plate and the solder for a first time at a first temperature to form a micro-pattern between the metallic plate and the solder comprises forming a convexly shaped micro-pattern between the metallic plate and the solder, and forming the metallic layer on the release agent comprises forming a concavely shaped micro-pattern on the metallic layer.

17. A metallic pattern for use in manufacturing a prism sheet, the metallic pattern manufactured through a method comprising:
preparing a metallic plate;
coating a solder containing tin Sn on the metallic plate;
heat-treating the metallic plate and the solder for a first time at a first temperature to form a micro-pattern between the metallic plate and the solder; and
selectively removing the solder from the metallic plate where the micro-pattern is formed.

18. A metallic pattern for use in manufacturing a prism sheet, the metallic pattern manufactured through a method comprising:
preparing a metallic plate;
coating a solder containing tin Sn on the metallic plate;
heat-treating the metallic plate and the solder for a first time at a first temperature to form a micro-pattern between the metallic plate and the solder;
selectively removing the solder from the metallic plate where the micro-pattern is formed;
coating a release agent on the micro-pattern;
forming a metallic layer on the release agent; and
separating the metallic layer from the metallic plate where the micro-pattern is formed.

19. A metallic pattern for use in manufacturing a prism sheet, the metallic pattern comprising:
a. metallic plate having a plurality of depressions and prominences arranged in a same axial direction; and,
a micro-pattern formed on a surface of the plurality of depressions and prominences, wherein the micro-pattern is an interface compound formed through a reaction between the metallic plate and a solder applied to the metallic plate to create the interface compound through heat treatment.

20. The metallic pattern of claim 19, wherein the plurality of depressions and prominences have a substantially triangular cross-section.

21. The metallic pattern of claim 19, wherein the metallic plate includes nickel and the micro-pattern includes a compound of nickel and tin.

22. The metallic pattern of claim 19, wherein the micro-pattern is convexly shaped on the metallic plate.

23. A metallic pattern for use in manufacturing a prism sheet, the metallic pattern comprising:
a plated layer having a plurality of depressions and prominences arranged in a same axial direction, the plurality of depressions and prominences having a substantially triangular cross-section; and,
a micro-pattern formed-on a surface of the plurality of depressions and prominences, wherein the micro-pattern is concavely shaped on the plated layer.

24. The metallic pattern of claim 23, wherein the plated layer is formed of nickel.

25. The metallic pattern of claim 23, wherein the micro-pattern on the plated layer is formed by forming the plated layer over a micro-pattern on a metallic plate, the micro-pattern on the metallic plate being an interface compound created through a reaction between the metallic plate and a solder applied to the metallic plate to create the interface compound through heat treatment.
